(19) United States
(12) Patent Application Publication
(10) Pub. No.: US 2008/0093731 A1
(43) Pub. Date: Apr. 24, 2008

(54) Cooled Integrated Circuit

(76) Inventors: Johann Heyen, Munchen (DE); Arne F. Jacob, Braunschweig (DE)

Correspondence Address: WHITHAM, CURTIS & CHRISTOFFERSON & COOK, P.C., 11491 SUNSET HILLS ROAD, SUITE 340, RESTON, VA, 20190, US

(21) Appl. No.: 11/572,216

(22) PCT Filed: Jul. 20, 2004
(86) PCT No.: PCT/DE04/01577

§ 371 Date: Jan. 17, 2007

(51) Int. Cl. H01L 23/46; H01L 23/66

(52) U.S. Cl. 257/713; 257/728; 257/E23.097

(57) ABSTRACT

The invention relates to an integrated circuit (1) having a plurality of substrate layers (2), active and/or passive components (3) embedded in the substrate layers (2), high-frequency lines conducted to the components (3) through the substrate layers (2), and cooling channels (6) for the dissipation of heat. The inventive circuit is characterized in that the cooling channels (6) are configured as high-frequency lines.

The invention relates to an integrated circuit having a plurality of substrate layers, active and/or passive components within the substrate layers, having radio-frequency lines which are connected through the substrate layers to the components, and having cooling channels for heat dissipation.

A structure such as this which is integrated three-dimensionally in a multilayer substrate, such as a low-temperature sintering multilayer ceramic LTCC, carries out the following function at the same time:
a) transmission of radio-frequency signals (RF) within the substrate between passive and active components, such as monolithically integrated millimetric wave circuits MMIC, which are mounted on the substrate surface; and
b) cooling of the active components.

By way of example, US 2002/0185726 A1 discloses active components being mounted in multilayer substrates of heat sinks, for example metal plates.

If the heat sink is not located in the immediate vicinity of the active component, it is also known from W. Kinzy Jones, Yanging Lin and Mingcong Gao: “Micro Heat Pipes in Low Temperature Cofire Ceramic (LTCC) Substrates”, in: IEEE Transactions on Components and Packaging Technologies, vol. 26, no. 1, March 2003, pages 110 to 115, for the heat to be dissipated through thermal vias which extend from the component to the heat sink through the multilayer substrate. These vias occupy space, which is no longer available for integration of other passive structures, such as radio-frequency or power supply lines, filters or couplers, etc.

Furthermore, it is known from Marlin R. Vogel: Liquid Cooling Performance for a 3-D Multichip Module and Miniature Heat Sink”, in: IEEE Transactions on Components, Packaging and Manufacturing Technology”, Part A, vol. 18, No. 1, March 1995, pages 68 to 73, for cooling channels to be incorporated in three-dimensional multilayer substrates in order, as an alternative to that with metallic heat sinks, to carry air, water or specific cooling liquids or cooling gases through the channels in the multilayer substrate to the active components. The component is cooled and the heat dissipated in this way. Thermal vias can also be used in this case for connection purposes, if, for technological or functional reasons, the cooling channel itself has to be well away from the component. The conventional measures for heat dissipation are space-consuming. This space is no longer available within multilayer substrates for other passive functional blocks. Furthermore, metal plates on the upper face or lower face of the substrate allow further active or passive components to be fitted to the surfaces only to a restricted extent.

The object of the invention is therefore to provide an improved integrated circuit.

The object is achieved according to the invention by the integrated circuit of this generic type by the cooling channels at the same time being in the form of radio-frequency lines.

The combined formation of the radio-frequency line routing and the cooling channel makes more effective use of the interior of the multilayer substrate, and creates free space for other functional blocks or components within and/or on the surface of the multilayer substrate.

Electrically conductive layer elements are preferably provided adjacent to the cooling channels or adjacent to the walls of the cooling channels, in order to form a radio-frequency line. In this case, by way of example, the layer elements can be arranged in order to form a microstrip line, a coplanar line or a waveguide. The waves of the cooling channel therefore need not be completely metalized. In fact, it is sufficient to have conductor elements which extend in the longitudinal direction of the cooling channels and are adjacent to the walls of the cooling channels. The walls of the cooling channel are completely metalized only in the special case of a waveguide.

Furthermore, a coaxial line can be formed by at least one further electric conductor, which extends in the longitudinal direction in the interior of a cooling channel in the form of a waveguide.

In the situation in which two layer elements are provided and are arranged parallel to opposite walls of the cooling channel, and the other walls of the cooling channel at right angles to them have no layer elements or metalization, a triplate line can be provided by an electrical conductor which extends in the longitudinal direction in the interior of the cooling channel.

Further embodiments for the radio-frequency lines are feasible and can easily be provided as appropriate for the requirements for the cut-off frequencies.

A further embodiment provides for the radio-frequency line to be produced with a large number of vias, which are arranged alongside one another, in order to form via fences which extend through the substrate layers adjacent to the cooling channels, which extend through the substrate layers adjacent to the cooling channels. This has the advantage that the functional elements such as supply lines for cooling liquid can be passed through between the vias.

The invention will be explained in more detail by way of example in the following text with reference to the attached drawing, in which:

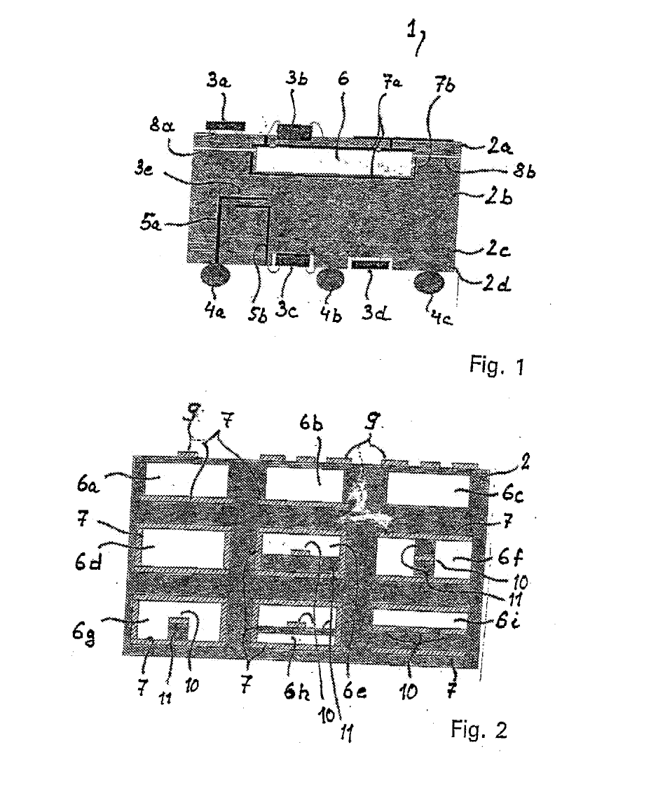

FIG. 1 shows a sectional view of an integrated circuit in the form of a multichip module having a combined radio-frequency and coolant line;

FIG. 2 shows a cross-sectional view through a substrate with various embodiments of radio-frequency lines provided by cooling channels; and

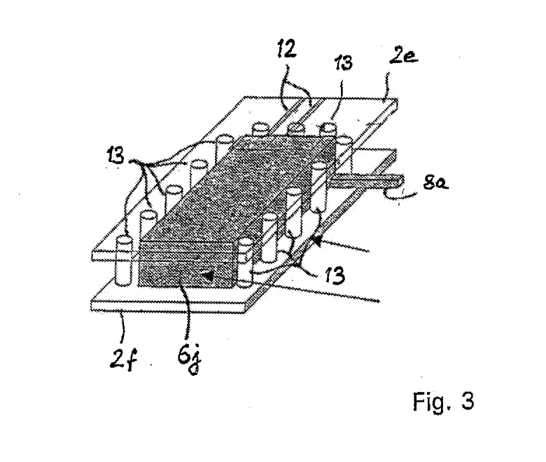

FIG. 3 shows a perspective illustration of one embodiment of a cooling channel with adjacent via fences in order to form a radio-frequency conductor.

FIG. 1 shows an integrated circuit 1 in the form of a multichip module having a plurality of substrate layers 2a, 2b, 2c, 2d, in layers one above the other. Active and passive components 3a, 3b, 3c, 3d are mounted on an upper substrate layer 2a, or are integrated in substrate layers 2c, 2d. Furthermore, bumps 4a, 4b, 4c can be provided in order to make external contact. In addition, vias 5a, 5b can be seen, which extend through the substrates 2b, 2c, 2d and are connected to line structures in order to form an integrated passive functional block 3e, such as a capacitance or an inductance.

A cooling channel 6 is incorporated in the substrate layer 2b and its upper and lower walls have electrically conductive layer elements 7 in the form of metalization on the walls. Electrically conductive layer elements 7 in the form of via fences 7b are provided parallel to the side walls of the cooling channel 6 are formed from a large number of vias which are arranged alongside one another and extend through the substrate 2b.

A cooling inlet line 8a and a cooling outlet line 8b extend through the substrate 2b parallel to the substrate surfaces, and each communicate with the cooling channel 6. Since the coolant is fed in at the side, this creates sufficient space for active and passive components 3 as well as interfaces to other mount substrates on the upper face and lower face of the integrated circuit 1. The available free space within the integrated circuit 1 can be used for passive integration.

Combined cooling and radio-frequency channels can also be provided in a corresponding manner, in a vertical form.

FIG. 2 shows a cross-sectional view through an integrated circuit 1 with a large number of cooling channels 6a to 6i.

In the case of a first cooling channel 6a, a strip conductor 9, which extends in the longitudinal direction of the cooling channel 6a, is provided above the cooling channel 6a. A metal surface 7 is located opposite this on the lower face of the cooling channel 6a, as an electrically conductive layer element. The cooling channel is thus in the form of a microstrip conductor.

In a second embodiment of a cooling channel 6b, three strip conductors 9, which likewise extend in the longitudinal direction of the cooling channel 6b, are located above the cooling channel 6b, at a distance from one another. Furthermore, the lower face of the cooling channel 6b is closed by a metal surface as an electrically conductive layer element 7. The cooling channel is thus in the form of a coplanar line with ground metalization on the rear face.

In a third embodiment of the cooling channel 6c, strip conductors 9 are located only above the cooling channel 6c. In comparison to the second embodiment of the cooling channel 6b, no metal surface is provided on the lower face of the cooling channel 6c. This thus results in a coplanar line.

A fourth embodiment of the cooling channel 6d is in the form of a waveguide, with all four walls of the cooling channel 6d being metalized. The cooling channel 6d is thus completely closed by electrically conductive layer elements 7.

A fifth embodiment of a cooling channel 6e is in the form of a waveguide, in a corresponding manner. A further conductor extends in the longitudinal direction in the interior of the cooling channel 6e on a substrate web 11, which is required only to provide mechanical robustness for the electrical inner conductor 10. A coaxial line is thus formed in the cooling channel 6e.

A sixth embodiment shows a cooling channel 6f with an electrical inner conductor 10, which is likewise supported above and below by substrate webs 11. In this embodiment, only the upper and lower walls of the cooling channel 6f have electrically conductive surfaces as layer elements 7. The side walls of the cooling channel 6f are in contrast approximately neutral for radio-frequency waves. This results in a triplate line.

A seventh embodiment shows a cooling channel 6g corresponding to the fifth embodiment. The electrical inner conductor 10 is in this case supported only by a substrate web 11, and not by a substrate level.

An eighth embodiment shows a cooling channel 6h, in which the electrical inner conductor 10 is supported by a substrate plate which extends between the side walls of the cooling channel 6h. The space above and below the substrate plate 11 thus remains free in order to carry cooling media.

A ninth embodiment shows a cooling channel 6i, whose upper face is closed by a metal layer as an electrically conductive layer element 7. As in the second embodiment, the lower face of the cooling channel 6i has associated electrical conductors 10, which are arranged alongside one another, extend in the longitudinal direction of the cooling channel 6i, and are buried in the substrate 2. A metal surface is arranged under the conductor 10 in a mirror-image form with respect to the layer element 7 on the upper face of the cooling channel 6i, as a second electrically conductive layer element 7.

Further refinements and combinations of layer elements 7 are feasible. The embodiment of the cooling channels 6 with combined radio-frequency lines may easily be designed using known means by a person skilled in the art, depending on the requirements, and in particular with regard to the cut-off frequencies.

The upper frequencies are restricted only by the material characteristics, production tolerances and design rules for the substrate technology used. Technologies that are compatible with millimetric waves for frequencies up to 110 GHz are known from the prior art.

The cooling channels 6 are filled with a suitable medium, or a suitable medium flows through them. With the exception of the fourth embodiment with the cooling channel 6d, there is no lower cut-off frequency for the described radio-frequency lines. In the case of waveguide arrangements according to the fourth embodiment, it is possible for waves to propagate above a specific cut-off frequency. This cut-off frequency is governed by the dielectric constant of the filling material and by the cross-sectional dimensions of the combined cooling-channel/radio-frequency-line structure. If the cross-sectional dimensions are relatively small, the useable frequency ranges, in which monomode propagation occurs are shifted upward. Extremely compact structures can thus be produced, in particular for high frequencies. The use of a filling material with a high dielectric constant makes it possible to also use the cooling-channel/radio-frequency-line structures for lower frequencies without the cross-sectional dimensions becoming excessively large. The available coolants which are used in multichip modules are suitable for use in combined cooling-channel/radio-frequency-line structures because of their low to moderate dielectric losses (loss angle tangent δ between 0.001 and 0.08) and a dielectric constant between 1.75 and 7.

FIG. 3 shows an embodiment such as this of a cooling channel 6j, which is embedded between an upper and a lower substrate 2a, 2f analogously to the fourth embodiment with the cooling channel 6d. An aperture-coupled coplanar line 12 is provided for radio-frequency coupling, and is placed on the upper face of the cooling channel 6j.

A large number of vias 13 are arranged alongside one another, at the side alongside the cooling channel 6j, between the substrates 2e and 2f, and each form a via fence. Furthermore, corresponding vias 13 are provided on the front face of the cooling channel 6j, in order to close the radio-frequency line that is formed by the via fences. Together with ground planes, the vias 13 form a waveguide in or on the substrates 2e, 2f, at least in the area between the vias 13.

A cooling channel supply line 8a is passed through between two vias 13 or an opening in the ground planes. Provided that the dimensions of the coolant supply line 8a and of a corresponding coolant outlet line 8b are small in comparison to the wavelength of the radio-frequency signal to be carried, the influence of the coolant supply line 8a and the coolant outlet line 8b on the radio-frequency characteristics remains low.

1. An integrated circuit (1) having a plurality of substrate layers (2), active and/or passive components (3) within the substrate layers (2), having radio-frequency lines which are connected through the substrate layers (2) to the components (3), and having cooling channels (6) for heat dissipation, characterized in that cooling channels (6) are at the same time in the form of radio-frequency lines.

2. The integrated circuit (1) as claimed in claim 1, characterized in that electrically conductive layer elements (7) are provided adjacent to the cooling channels (5) or adjacent to the walls of the cooling channels (6) in order to form a radio-frequency line.

3. The integrated circuit (1) as claimed in claim 2, characterized in that the layer elements (7) are arranged to form a microstrip line, a coplanar line or a waveguide.

4. The integrated circuit (1) as claimed in claim 2, characterized by at least one further electrical conductor (10), which extends in the longitudinal direction in the interior of a cooling channel (6), which is in the form of a waveguide, in order to form a coaxial line.

5. The integrated circuit (1) as claimed in claim 2, characterized by two layer elements (7), which are arranged parallel to opposite walls of the cooling channel (6), and an electrical conductor (10), which extends in the longitudinal direction in the interior of the cooling channel (6), in order to form a triplate line, with the other walls of the cooling channel 6 not having any associated layer elements (7).

6. The integrated circuit (1) as claimed in claim 2, characterized by via fences, which extend through the substrate layers (2) adjacent to the cooling channels (6), with a large number of vias (13) which are arranged alongside one another in order to form a radio-frequency line.
